(19) United States
(12) Patent Application Publication
(10) Pub. No.: US 2026/0262270 A1
(43) Pub. Date: Sep. 3, 2026

(54) BURIED-CHANNEL SEMICONDUCTOR HETEROSTRUCTURES WITH ENHANCED BAND OFFSET

(71) Applicant: TECHNISCHE UNIVERSITEIT DELFT, Delft (NL)

(72) Inventors: Giordano Scappucci, Delft (NL); Alberto Tosato, Delft (NL)

(21) Appl. No.: 18/863,569

(22) PCT Filed: May 4, 2023
(86) PCT No.: PCT/NL2023/050239

§ 371 Date: Nov. 6, 2024

(30) Foreign Application Priority Data
May 6, 2022 (NL) 2031791

(51) Int. Cl. H10D 62/815; H10D 62/822

(52) U.S. Cl. CPC H10D 62/8164; H10D 62/822

(57) ABSTRACT

Buried quantum well semiconductor heterostructures are described comprising: a strained quantum well layer provided over a base layer, an inorganic dielectric layer, preferably an oxide layer, provided over the quantum well layer; and, a barrier layer provided between the quantum well layer and the oxide layer, wherein the barrier layer includes a strained semiconductor superlattice for increasing the band offset in the barrier layer.

### CROSS-REFERENCE TO RELATED APPLICATION

This Application is a Section 371 National Stage Application of International Application No. PCT/NL2023/050239, filed May 4, 2023 and published as WO 2023/214872 A1 on Nov. 9, 2023, in English, the contents of which are hereby incorporated by reference in their entirety.

### TECHNICAL FIELD

The disclosure relates to buried-channel semiconductor heterostructures, and, in particular, though not exclusively, to buried-channel semiconductor heterostructures having an enhanced band offset and to gate-based semiconductor devices comprising such buried-channel semiconductor heterostructure.

### BACKGROUND

Buried-channel semiconductor heterostructures are an archetype material platform for the fabrication of quantum devices. In these buried-channel semiconductor heterostructures, a quantum well (for example Ge, Si, SiGe, etc . . . ) is separated from the control electrodes defining the quantum devices (for example a quantum dot qubit) by a semiconductor barrier and an oxide layer. The thickness and chemical composition of the barrier limit the charge that is hosted in the quantum well to a saturation density and influence the tunnelling rate of charges from the quantum well to the SiGe-barrier/Oxide interface.

Sammak et al., described in their article Shallow and Undoped Germanium Quantum Wells: A Playground for Spin and Hybrid Quantum Technology, Adv. Funct. Mater. 2019, 29, 1807613, a platform for fabricating well-defined and controllable quantum devices, for example quantum dots, that can be obtained by positioning the channel near the surface and control electrodes. In this way, the shape and position of quantum devices can be controlled precisely and effectively by applying a voltage to the control electrodes. However, proximity to the oxide layer degrades the electrical properties of the channel, (and, hence, for example, of the qubits) for a number of reasons. First, unwanted charge at the oxide/semiconductor interface interferes with the electrostatic potential created by the gates, meaning that the quantum devices do not exhibit the characteristics as designed. Further, charge from the buried channel can tunnel to or into the oxide/semiconductor interface, creating instabilities in the device control and operation. Additionally, the screening effect of the charge accumulated at the oxide/semiconductor interface limits the device operating window.

Known solutions to suppress tunneling or to increase saturation density, are based on the use of heterostructures of a larger valence-band offset AEv to increase the tunneling barrier and induce more charge, which can be implemented for example by increasing the Si composition in the SiGe barrier of a Ge/SiGe heterostructure. However, misfit dislocations induced by a larger lattice mismatch between the Ge active layer and the relaxed GeSi cap layer may further degrade the channel mobility.

Hence, from the above, it follows that there is a need in the art for improved buried-channel semiconductor heterostructures. In particular, there is a need in the art for gate-based devices comprising an improved buried-channel semiconductor heterostructure wherein the characteristics of the device are robust against influences of the oxide/semiconductor gate interface.

### SUMMARY

It is an objective of the embodiments in this disclosure to reduce or eliminate at least one of the drawbacks known in the prior art.

Generally, the embodiments in this application relate to the insight that inserting a plurally of highly strained thin semiconductor layers in the semiconductor barrier of a heterostructure (wherein the strained thin layers are of a different semiconductor material than the semiconductor material of the barrier layer) increases the band offset in the barrier layer. This way, electrical insulation of the quantum well is increased and accumulation of interface charge at the oxide/semiconductor interface due to electric active defects and other interface states and/or due to tunnelling of charges from buried channel to the surface of the heterostructure (i.e. the semiconductor/oxide interface of the heterostructure), is suppressed. These band offset layers are typically very thin and highly strained to achieve a large band offset without disrupting the crystalline environment and may be inserted multiple times in the semiconductor barrier.

The band offset layers may form a highly strained semiconductor superlattice in the barrier layer that is configured to increase the band offset in the barrier layer. Here, the terms semiconductor superlattice generally refers to a structure made up of alternating (periodic or non-periodic) ultra-thin layers (in the nanometer range) of different semiconductor materials which are engineered so that the properties of the structure comprising such superlattice are modified. Selection of the parameters of a plurally of highly strained thin semiconductor layers (thickness and number of the band offset layers, position of the band offset layers relative to the semiconductor/oxide interface of the heterostructure) may be used to engineer the superlattice so that the saturation density of the quantum well can be increased, due to confining and thus moving up the states at the surface in energy, compared to current state of the art where only a surface channel is formed. Insertion of a plurally of highly strained thin semiconductor layers between the oxide layer and the quantum well layer of the heterostructure overcomes the drawback of misfits dislocations, while keeping the advantage of increasing the band offset and, consequently, increasing the saturation density in the quantum well and reducing the tunnelling of charged form the quantum well to the semiconductor/oxide interface.

In an aspect, the invention relates to a buried quantum well semiconductor heterostructure structure comprising: a strained quantum well layer provided over a base layer; an insulating inorganic dielectric layer, for example an oxide layer such as an SiO₂ layer, an Al₂O₃ layer or a layer of any other suitable high-k dielectric material, provided over the quantum well layer; and, a semiconductor barrier layer provided between the quantum well layer and the dielectric layer, wherein the barrier layer includes a plurally of highly strained thin semiconductor layers in the semiconductor barrier to increase the band offset of the heterostructure structure at the interface between the barrier layer and the dielectric layer.

In an embodiment, the plurally of highly strained thin semiconductor layers in the semiconductor barrier may form a semiconducting superlattice.

In an embodiment, the superlattice may include layers of the semiconductor barrier material separated by two or more semiconductor band offset layers wherein the band offset layer is of a semiconductor material that increases the band offset in the semiconductor barrier layer close to the semiconductor/dielectric interface of the heterostructure. Hence, semiconductor superlattice may include at least two band offset layers. In an embodiment, the band offset layers are of an intrinsic (undoped) semiconductor material.

In an embodiment, the band offset layers may have a thickness between 0.8 and 5 nm, preferably between 0.9 and 4 nm, more preferably between 1 and 3 nm. In an embodiment, the thickness of a strained band offset layer is selected below a critical thickness above which strain of the strained band offset layer relaxes thereby introducing dislocations in the band offset layer.

In an embodiment, the superlattice may comprise between 2 and 20 band offset layers, preferably between 4 and 10 band offset layers.

In an embodiment, the thickness of the barrier layer is between 20 and 100 nm, preferably between 30 and 80 nm.

In an embodiment, the thickness of the quantum well layer may be between 4 and 40 nm, preferably between 6 and 30 nm.

In an embodiment, the heterostructure may comprise a Si quantum well layer, a SiGe barrier layer and a Ge/SiGe superlattice.

In an embodiment, the heterostructure may comprise a Ge quantum well layer, a SiGe barrier layer and a Si/SIGe superlattice.

In an embodiment, the relative SiGe concentration of the barrier layer and/or the Si/Ge layers of the superlattice is selected between Si_{0.1}Ge_{0.9} and Si_{0.1}Ge_{0.9}. In an embodiment, relative SiGe concentration of the barrier layer and/or the Si/Ge layers of the superlattice may be around Si_{0.2}Ge_{0.8}.

In an embodiment, the quantum well structure may further comprise a conductive layer provided over the oxide layer.

In an embodiment, the quantum well may comprise a compressive strained quantum well and the barrier layer may comprise one or more tensile strained band offset layers. In an embodiment, the quantum well may be a tensile strained quantum well and the barrier layer may comprise one or more compressively strained band offset layers.

In an embodiment, the spacing of the band offset layers may be an asymmetric spacing, wherein the asymmetric spacing is selected such that the density of band offset layers close to the oxide layer is higher than the density of band offset layers further away from the oxide layer. An asymmetric spacing may be used such that the density of band offset layers close to the oxide interface is higher than the density away from the oxide layer. Increasing the amount of band offset layers close to the oxide interface may maximize the effect of enhancing the saturation density.

In an embodiment, the barrier layer may be configured as a semiconductor superlattice.

In a further aspect, the embodiments relates to a semiconductor device, for example a gated semiconductor device, comprising a buried quantum well semiconductor heterostructure according to any of the embodiments as described above. The embodiments will be further illustrated with reference to the attached drawings. It will be understood that the embodiments are not in any way restricted to the examples in the drawings.

### BRIEF DESCRIPTION OF THE DRAWINGS

FIG. 1 depicts a schematic of a conventional buried quantum well heterostructure;

FIG. 2A-2C depict the band structure, the probability density as a function of the thickness and the carrier concentration as a function of gate voltage for a conventional buried Ge-based quantum well structure;

FIG. 3 depicts a schematic of a buried quantum well structure comprising according to an embodiment.

FIG. 4A-4C depict the band structure, the probability density as a function of the thickness and the carrier concentration as a function of gate voltage for a buried Ge-based quantum well structure according to an embodiment;

FIG. 5A-5C depict the band structure, the probability density as a function of the thickness and the carrier concentration as a function of gate voltage for a conventional buried Si-based quantum well structure.

FIG. 6A-6C depict the band structure, the probability density as a function of the thickness and the carrier concentration as a function of gate voltage for a buried Si-based quantum well structure according to an embodiment;

FIG. 7 shows pictures of part of a buried quantum well structure according to an embodiment.

### DESCRIPTION OF THE EMBODIMENTS

The embodiments in this application aim to solve or at least substantially reduce interface problems related to unwanted charge that may accumulate at the oxide/semiconductor interface of buried-channel semiconductor heterostructures. Interface charges may interfere with the electrostatic potential created by for example a gate that is positioned on top of the heterostructure, meaning that devices, such as field effect transistors or quantum devices, do not meet the design specifications. The interface charge or the interface charge density is the net charge or charge density at the oxide/semiconductor interface. These charges may arise from electric active defects and other interface states at and/or close to semiconductor/oxide interface; and/or, from tunnelling of charges from the buried channel to the surface of the heterostructure.

The embodiments address these problems by inserting within the semiconductor barrier of a buried-channel semiconductor heterostructure a plurality of highly strained ultra-thin semiconductor layers of a (intrinsic) semiconductor material that is different from semiconductor material of the barrier layer, to increase (boost) the band offset of the barrier layer of buried quantum well heterostructures. This way, electrical insulation of the quantum well is increased and tunnelling to the surface interface is suppressed. These ultra-thin layers, which may be referred to as band offset layers, in the barrier layer of the buried quantum well heterostructure are typically thinner compared to the other the other layers of the heterostructure. Hence, the plurality of ultra-thin semiconductor layers in the barrier layer may form a superlattice.

The band offset layers may be highly strained to achieve a large band offset without disrupting the crystalline environment. Specifically, by choosing an adequate distance between the band offset layers and the oxide/semiconductor interface of buried-channel semiconductor heterostructure, the band offset may be engineered so that the saturation density of the quantum well may be increased, by confining and thus moving the states at and/or close to the oxide/semiconductor interface up in energy, compared to current state of the art buried-channel semiconductor heterostructure.

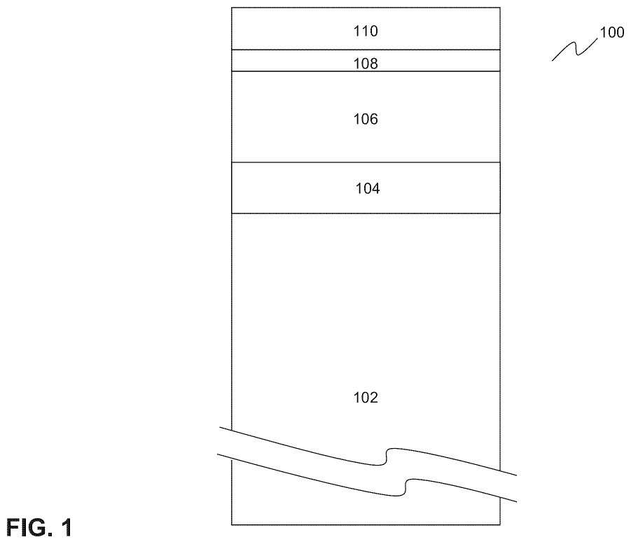

FIG. 1 depicts a schematic of a buried quantum well heterostructure. In particular, the figures depict a buried quantum well heterostructure 100 comprising a relatively thick base layer 102, a strained quantum well layer 104, a semiconductor barrier layer 106 and an inorganic dielectric layer 108, e.g. an oxide layer such as a SiO₂ or an Al₂O₃ layer, for separating the quantum well structure from a metal or metallic gate layer 110. The depicted structure may form a basic structure for gated semiconductor structures, such as gated undoped SiGe buried quantum well structures that can be used in high-performance field effect transistors and quantum dot structures for quantum technology.

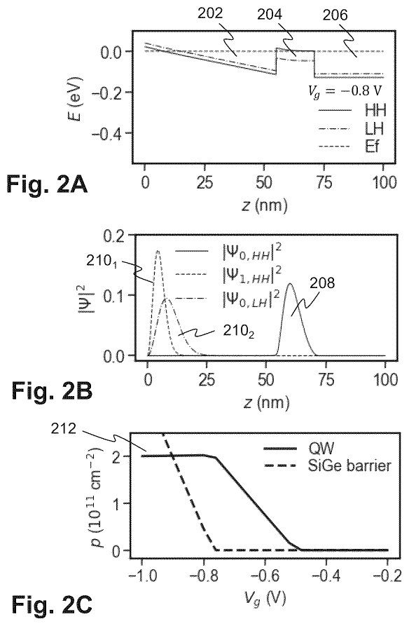

An example of a band structure and carrier concentration as a function of gate voltage for a conventional buried quantum well structure, in this example a Ge-type buried quantum well (QW) structure is shown in FIG. 2A-2C. In particular, FIG. 2A shows the heavy holes (HH) and light holes (LH) band edges of the heterostructure, relative to the Fermi energy (Ef) that is set to zero in the simulations. The x-axis represents the distance (z) relative to the surface of the heterostructure. The gate voltage (Vg) in these simulations is set to −0.8 V. As shown in the figure the structure is a 55 nm deep Ge/Si_{0.2}Ge_{0.8} QW. The structure includes a SiGe barrier 202 in range 0<z<55, a Ge QW 204 located in the range 55≤z≤71, and a SiGe substrate 206 located at z>71. For z<0 there is the oxide layer that separates the metal gate from the heterostructure (not shown in in the plot).

FIG. 2B shows the probability density for the occupied subbands only.

These are the HH or LH subbands with energy above the Fermi energy. The subscript of Ψ indicates the subband energy level (0, 1, . . . ) and whether it belongs to the HH or LH band. This figure shows that the heterostructure has one occupied subband 208 in the QW as desired, but also two occupied subbands 210_{1,2} in SiGe barrier close to the oxide interface (on the left side of the plot), one in the HH and the other in the LH band.

FIG. 2C shows the total charge accumulated in the QW region and in the SiGe region as a function of gate voltage (V_{g}). The figure shows that if V_{g} is swept to negative values, charge accumulates in the QW. The amount of charge in the QW increases linearly with V_{g} until the subbands in the SiGe barrier cross the Fermi energy and start to get populated. From this point onwards a further increase in negative gate voltage increases the population in the SiGe barrier leaving the population in the QW basically unchanged. The maximum density achievable in the QW before the population of the subbands in the SiGe barrier is referred to as the saturation density 212.

Hence, the graphs show that the subbands close to the interface cause unwanted charge at the oxide/semiconductor interface which interferes with the electrostatic potential created by the gates, meaning that the quantum devices do not exhibit the characteristics as designed. To address the formation of unwanted subbands at the semiconductor-oxide interface, during the growth of the heterostructure a plurality of ultra-thin Silicon layers are introduced which will increase the band offset of the heterostructure at the oxide/semiconductor interface. These ultra-thin layers of a thickness between 0.8-5 nm may be referred in this application as band offset layers.

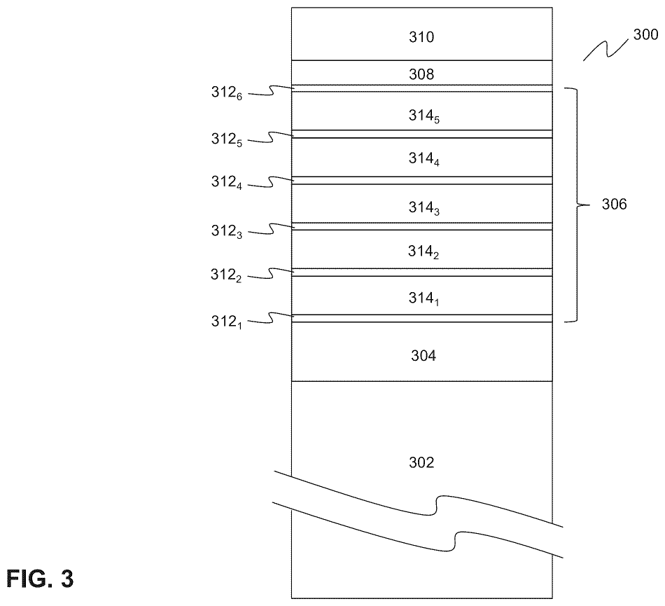

FIG. 3 depicts a schematic of a buried quantum well structure comprising according to an embodiment. Similar to the structure of FIG. 1, the buried quantum well structure 300 comprises a relatively thick base layer 302, a compressively strained quantum well layer 304, a barrier layer 306, an oxide layer 308 for separating the quantum well structure from a metal or metallic gate layer 310. In this embodiment however, the barrier structure includes a plurality of ultra-thin Si layers 312₁₋₆ located in the SIGe barrier layer. As will be shown hereunder in more detail, the ultra-thin layers may be very thin and highly strained to achieve a large band offset without disrupting the crystalline environment and may be inserted multiple times in the semiconductor barrier to induce a band offset in the bandstructure of the buried heterostructure. These layers in the barrier layer may therefore be referred to as band offset layers.

In this application, the term “highly strained” refers to strains with absolute value >2%. For example, a silicon band offset layer on a Si_{0.2}Ge_{0.8} barrier layer will have a strain of around 3%, wherein a strained quantum well described in this application is typically strained with an absolute value of strain <1%. For example a Ge quantum well on Si_{0.2}Ge_{0.8} has an in-plane compressive strain of ε_{∥}=−0.63%.

In this example, the heterostructure may include a relatively thick Si_{0.2}Ge_{0.8} base layer, a 6 nm Ge quantum well layer, and a barrier layer comprising a stack of alternating 1 nm thick Si band offset layer and 12 nm thick Si_{0.2}Ge_{0.8} layers. The barrier layer may comprise a stack of alternating ultra-thin Si band offset layers 312₁₋₆ and Si_{0.2}Ge_{0.8} layers 314₁₋₆ thus forming a highly strained semiconducting superlattice. As will be described hereunder in greater detail, many heterostructures other than the one shown in FIG. 3 are possible without departing from the teaching of the embodiments.

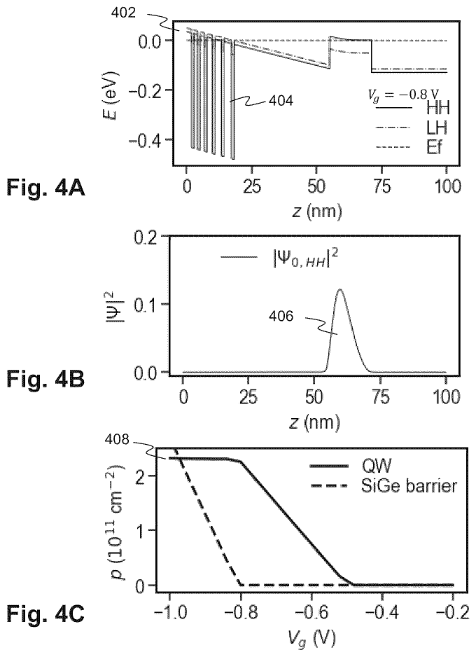

The effect of the band offset layers in the barrier layer is illustrated with reference to FIG. 4A-4C, which show graphs of the band structure and carrier concentration as a function of gate voltage for a buried Ge quantum well structure comprising a plurality of Si band offset layers. In particular, FIG. 4A shows the band structure of the same heterostructure of FIG. 2, but now including a plurality of Si band offset layers in the barrier layer of the heterostructure. In this example, the Si/SiGe superlattice may have 1 nm thick Si band offset layers and SiGe layers with different thicknesses (asymmetric spacing). The semiconductor superlattice may include a plurality of band offset layers, in this example five band offset layers, positioned at 1.96, 4.22, 6.83, 9.84, 13.31 and 17.32 nm relative to the semiconductor-oxide interface. An asymmetric spacing may be used such that the density of band offset layers close to the oxide interface is higher than the density away from the oxide layer. Increasing the amount of band offset layers close to the oxide interface may maximize the effect of enhancing the saturation density. As shown in this figure, when compared to band structure of the conventional heterostructure of FIG. 2A the Si band offset layers introduce a substantial increase in the band-offset 402 in the HH and LH bands of the SiGe barrier, wherein the band-offset in the HH band is the most prominent.

FIG. 4B shows the probability density function of the occupied subbands. This figure shows an occupied subband in the QW 406, but no occupied subbands in the SiGe barrier at the oxide/semiconductor interface (these simulations are at the same gate voltage of simulation in FIG. 2 to allow for comparison). The subbands in the SiGe barrier are pushed further away from the Fermi energy by the presence of the Si band offset layers, and will therefore get occupied only at substantial larger gate voltages.

As shown in FIG. 4C, the effect of the Si band offset layers is to shift to larger negative gate voltages the onset of the population of the SiGe barrier, allowing to reach a larger saturation density in the QW. The graph shows a 15% increase in saturation density 408 for the heterostructure comprising the plurality of Si band offset layers.

Also, as shown in FIG. 4A-4B the presence of the Si band offset layers in the SiGe barrier region between the Ge quantum well and the oxide interface introduces a potential barrier suppressing tunnelling from the quantum well into trap states and/or the triangular well at the semiconductor-oxide interface.

Further, at large negative gate voltages the triangular quantum well at the interface has only light holes (LH) available states. The heavy holes (HH) states are pushed away due to the Si barriers. This way, compared conventional buried heterostructures, the formation of subbands near the oxide interface can be substantially reduced.

Additionally, it surprisingly provides a substantial increase (15%) in the saturation density of the quantum well. This way, when using a buried heterostructure including such Si band offset layers in a gated device, the device will have superior characteristics compared to devices using conventional buried quantum well structures.

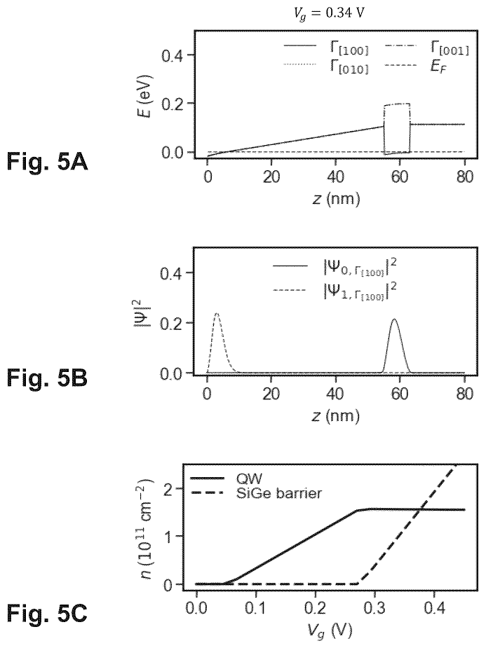

It is submitted that the embodiments are not limited to Ge-type buried quantum well structure, but may be extended to other types of quantum well as well. For example, in a further embodiment, Ge band offset layers can be introduced in the barrier layer of a Si-based buried quantum well to achieve similar advantageous effect as described with reference to FIG. 4. For example, FIG. 5A-5C depict the band structure and carrier concentration as a function of gate voltage for a conventional buried Si-based quantum well structure.

FIG. 5A shows the Γ band-edges for a conventional Si based quantum well structure in the [100], [010], [001] directions, wherein [100] corresponds to the growth direction z. The band edges energy is relative to the Fermi energy (Ef) which is set to zero. Further, the gate voltage (V_{g}) is set to 0.34 V. The structure includes a SIGe barrier located in the region 0<z<55, a Si QW located in range 55≤z≤71 and a SiGe substrate located for z>71 the. For z<0 there is an oxide layer that separates the metal gate from the heterostructure (these are not in the plot).

FIG. 5B shows the probability density for the occupied subbands only. These are the Γ_{[100]} subbands with energy above the Fermi energy, wherein the subscript of Ψ indicates the subband energy level (0, 1, . . . ) and the respective band (Γ_{[100]}). The heterostructure with no Ge band offset layers shows one occupied subband in the QW as desired, but also one occupied subband in SiGe barrier close to the interface with the oxide (on the left side of the plot).

FIG. 5C shows the total charge (n) accumulated in the QW region and in the SIGe region as a function of gate voltage (Vg). As Vg is swept to more positive values, charge accumulates in the QW. The amount of charge in the QW increases linearly with Vg until the subbands in the SiGe barrier cross the Fermi energy and start to get populated. From this point onwards a further increase in gate voltage increases the population in the SiGe barrier leaving the population in the QW basically unchanged (the maximum saturation density).

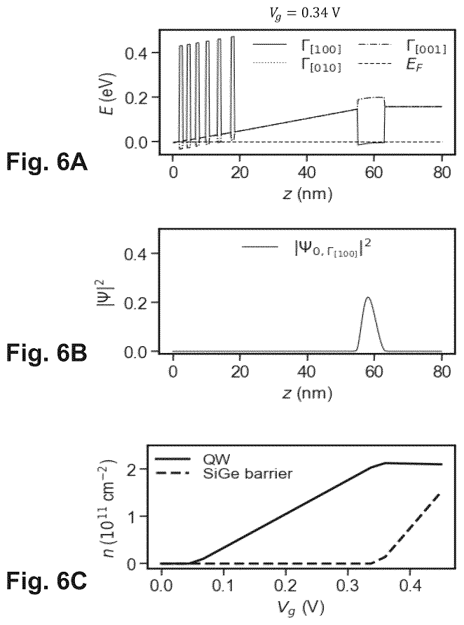

Thus, similar to the Ge-type buried heterostructure, also conventional Si-type buried heterostructures exhibits unwanted charge build up at the oxide interface. FIG. 6A-6C show that the effect of Ge-band offset layers in the barrier layer of a Si-type burrier heterostructure that has the same basic structure as the heterostructure of FIG. 5.

FIG. 6A shows a graph of the band edges of the Si-based burrier heterostructure. The Ge band offset layers are 1 nm thick and have an asymmetric spacing similar to structure of the Ge-type buried heterostructure. The Ge band offset layers introduce a band-offset in the Γ band of the SiGe barrier, with a positive band-offset for the Γ_{[100]} causing suppression of charge buildup at the oxide interface.

FIG. 6B shows a heterostructure comprising a superlattice of band offset layers (biased at the same gate voltage as FIG. 6A) having an occupied subband in the QW but no occupied subbands at the SiGe-oxide interface. This subbands are pushed further away from the Fermi energy by the presence of the Ge band offset layers, and will therefore get occupied only at (much) larger gate voltages compared to the conventional buried quantum well structure of FIG. 5.

FIG. 6C shows the effect of the Ge band offset layers shifting the onset of the population of the SiGe barrier to larger gate voltages, allowing to reach a larger saturation density in the QW. In this particular embodiment 35% increase in saturation density for the heterostructure with band offset layers was observed. Hence, when using a buried heterostructure including such Si band offset layers in a gated device, the device will have superior characteristics compared to devices using conventional buried quantum well structures.

Thus, as shown by the embodiments in this application, inserting thin semiconductor layers (referred to as band offset layers) in the semiconductor barrier of a heterostructures wherein the band offset layers are of a different semiconductor material than the material of the semiconductor barrier thereby including the band offset of the structure at the semiconductor/dielectric interface. This way, electrical insulation of the quantum well is increased and tunnelling of charge to the surface, i.e. the oxide interface, is suppressed. The semiconductor band offset layers are typically very thin and highly strained to achieve a large band offset without disrupting the crystalline environment and may be inserted multiple times in the semiconductor barrier. This way, the band offset layers may form a highly strained, semiconducting superlattice in the barrier layer. Selection of the parameters of the superlattice (thickness and number of the band offset layers, position of the superlattice relative to the semiconductor/oxide interface of the heterostructure) may be used to engineer the superlattice so that the saturation density of the quantum well can also be increased, due to confining and thus moving up in energy the states at the surface, compared to current state of the art where a surface channel is formed.

In embodiment, the band offset layers in the superlattice may be of a thickness between 0.8 and 4 nm, preferably between 0.9 and 4 nm, more preferably between 1 and 3 nm. More generally, the thicknesses of the band offset layers may be selected such that they do not induce too much strain due to the lattice mismatch between on the one hand the Si or Ge layers and on the other hand the SiGe layers so that it will distort the crystalline (epitaxial) structure.

In an embodiment, if the quantum well is a Ge quantum well, the superlattice may be a SI/SIGe superlattice. In another embodiment, if the quantum well is a Si quantum well, the superlattice may be a Ge/SiGe superlattice. In an embodiment, the band offset layers in the superlattice may have substantially the same thickness or may be of different thicknesses. In an embodiment, the SIGe layers in the superlattice may have substantially the same thickness or may be of different thicknesses.

In a further embodiment, the superlattice may be localized in a predetermined part of the barrier layer. In another embodiment, the barrier layer may be a superlattice, In an embodiment, the number of band offset layers in a superlattice may be selected between 1 and 20, preferably between 4 and 10. In an embodiment, the thickness of the barrier layer (measured from the semiconductor/oxide interface to the quantum well layer) may be between 10 and 100 nm, preferably between 20 and 80 nm. Further, the thickness of the quantum well layer may be between 4 and 40 nm, preferably between 6 and 30 nm. Further, the relative SiGe concertation of the SiGe layers of a superlattice may vary between Si_{0.3}Ge_{0.7} and Si_{0.1}Ge_{0.9}.

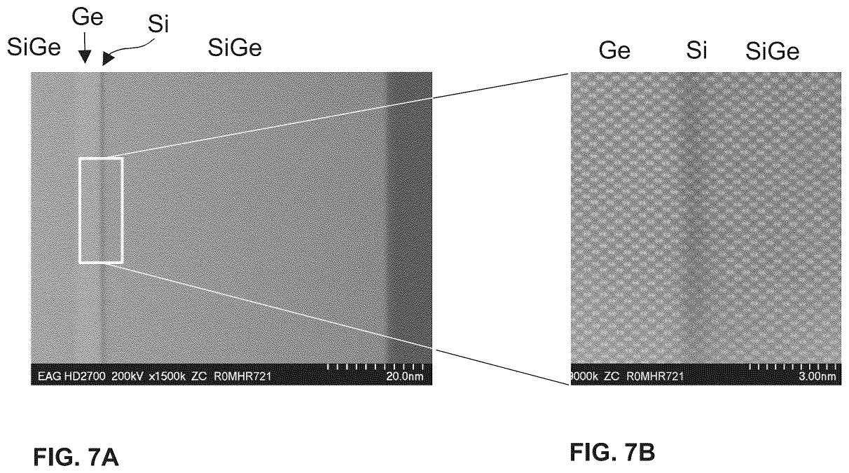

FIGS. 7A and 7B show tunnelling electron microscopy (TEM) images of part of a buried quantum well structure according to an embodiment. In particular, FIG. 7A shows a TEM picture of a SiGe/Ge/SiGe structure including one Si band offset layer at the interface between the Ge quantum well and the SiGe barrier layer. FIG. 7B is a TEM picture of an inset at the Si-SiGe barrier layer. As shown in this picture an approximately 1 nm Si layer is epitaxially formed shown that the Si layer does not affect the epitaxy of the Ge and the SIGe.

The description and drawings merely illustrate the principles of the embodiments. It will thus be appreciated that those skilled in the art will be able to devise various arrangements that, although not explicitly described or shown herein, embody the principles of the invention and are included within its spirit and scope. More generally, the teaching of the embodiments can be applied to components based on semiconductor materials of column V, columns III-V, and to any compatible substrate.

Furthermore, all examples recited herein are principally intended expressly to be only for pedagogical purposes to aid the reader in understanding the teaching of the embodiments and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass equivalents thereof.

1. A buried quantum well semiconductor heterostructure comprising:
a strained quantum well layer provided over a base layer;
an oxide layer provided over the quantum well layer;
a conductive layer provided over the oxide layer; and
a SiGe barrier layer provided between the strained quantum well layer and the oxide layer, the barrier layer including a plurality of highly strained semiconductor layers, each highly strained semiconductor layer having a thickness smaller than 5 nm;
wherein the strained quantum well layer is a strained Si quantum well layer or a strained Ge quantum well layer and the plurality of highly strained semiconductor layers are highly strained Ge layers or highly strained Si layers respectively, wherein a strain of a highly strained semiconducting layer has an absolute value of larger than 2%.

2. A buried quantum well semiconductor heterostructure according to claim 1 wherein the plurality of highly strained semiconductor layers comprises between 1 and 20 band offset layers, preferably between 4 and 10 band offset layers.

3. A buried quantum well semiconductor heterostructure according to claim 1 wherein the thickness of the barrier layer is between 10 and 100 nm, preferably between 20 and 80 nm.

4. A buried quantum well semiconductor heterostructure according to claim 1 wherein the thickness of the quantum well layer is between 4 and 40 nm, preferably between 6 and 30 nm.

5. A buried quantum well semiconductor heterostructure according to claim 1 wherein SiGe concentration of the barrier layer is selected between Si_{0.1}Ge_{0.9} and Si_{0.9}Ge_{0.1}.

6. A buried quantum well semiconductor heterostructure according to claim 1 wherein the quantum well is a compressive strained quantum well and the plurality of highly strained semiconductor layers are tensile strained layers or wherein the quantum well is a tensile strained quantum well and the plurality of highly strained semiconductor layers are compressive strained layers.

7. A buried quantum well semiconductor heterostructure according to claim 1 wherein a spacing of the plurality of highly strained semiconductor layers is an asymmetric spacing, the asymmetric spacing being selected such that a density of band offset layers close to the oxide layer is higher than a density of band offset layers further away from the oxide layer.

8. A buried quantum well semiconductor heterostructure according to claim 1 wherein the barrier layer is configured as a superlattice comprising the plurality of highly strained semiconductor layers.

9. A semiconductor device comprising a buried quantum well semiconductor heterostructure comprising:
a strained quantum well laver provided over a base layer;
an oxide layer provided over the quantum well layer;
a conductive layer provided over the oxide layer; and
a SiGe barrier layer provided between the strained quantum well layer and the oxide laver, the barrier laver including a plurality of highly strained semiconductor layers, each highly strained semiconductor layer having a thickness smaller than 5 nm:
wherein the strained quantum well layer is a strained Si quantum well layer or a strained Ge quantum well layer and the plurality of highly strained semiconductor layers are highly strained Ge layers or highly strained Si layers respectively, wherein a strain of a highly strained semiconducting laver has an absolute value of larger than 2%.

10. The semiconductor device according to claim 9 wherein the plurality of highly strained semiconductor layers comprises between 1 and 20 band offset layers, preferably between 4 and 10 band offset layers.

11. The semiconductor device according to claim 9 wherein the thickness of the barrier layer is between 10 and 100 nm, preferably between 20 and 80 nm.

12. The semiconductor device according to claim 9 wherein the thickness of the quantum well layer is between 4 and 40 nm, preferably between 6 and 30 nm.

13. The semiconductor device according to claim 9 wherein SiGe concentration of the barrier layer is selected between Si_{0.1}Ge_{0.9} and Si_{0.9}Ge_{0.1}.

14. The semiconductor device according to claim 9 wherein the quantum well is a compressive strained quantum well and the plurality of highly strained semiconductor layers are tensile strained layers or wherein the quantum well is a tensile strained quantum well and the plurality of highly strained semiconductor layers are compressive strained layers.

15. The semiconductor device according to claim 9 wherein a spacing of the plurality of highly strained semiconductor layers is an asymmetric spacing, the asymmetric spacing being selected such that a density of band offset layers close to the oxide layer is higher than a density of band offset layers further away from the oxide layer.

16. The semiconductor device according to claim 9 wherein the barrier layer is configured as a superlattice comprising the plurality of highly strained semiconductor layers.

17. The semiconductor device of claim 9 wherein the semiconductor device is a gated semiconductor device.
